(19) United States
(12) Patent Application Publication
(10) Pub. No.: US 2016/0247977 A1
(43) Pub. Date: Aug. 25, 2016

(54) LED INTEGRATED PACKAGING STRUCTURE AND METHOD

(71) Applicant: DM Lighting Technologies Inc., Montclair, CA (US)

(72) Inventors: Dun-Hua Cao, Kunshan Suzhou (CN); Xu-Zhi Li, Kunshan Suzhou (CN); Yue-Shan Liang, Kunshan Suzhou (CN)

(21) Appl. No.: 14/626,825

(22) Filed: Feb. 19, 2015

(51) Int. Cl. H01L 33/48; H01L 33/52; H01L 33/62; H01L 25/075; H01L 33/36

(52) U.S. Cl. CPC H01L 33/486; H01L 25/0753; H01L 33/36; H01L 33/62; H01L 33/52; H01L 2933/0016; H01L 2933/005; H01L 2933/0066

(57) ABSTRACT

An LED integrated packaging structure is disclosed including a base; at least one LED chip which is fixedly connected on the base, the LED chip having positive and negative electrodes; an insulation layer which is disposed on surfaces of the base and the LED chip and the, wherein surfaces of the positive and negative electrodes of the LED chip are exposed from the insulation layer; at least two connecting electrodes which are disposed on the base and the LED chip.

### CROSS-REFERENCE TO RELATED APPLICATIONS

Not Applicable.

### BACKGROUND

The present invention relates to a light emitting diode (LED) integrated packaging technology, and particularly, to an LED integrated packaging structure and an LED integrated packaging method.

LED products are widely deployed for lighting and decoration. LED integrated packaging is important for manufacturing LED products.

In current LED integrated packaging technology, packaging of chips and substrates is basically done in a traditional way in which a chip is generally fixed to a substrate and then the chip and the substrate are connected by a wiring process (using gold wires). Disadvantages of the current LED integrated packaging technology includes the following: only a single mesa device can be packaged, and a plurality of mesa devices cannot be simultaneously packaged; gold wires used in the wiring process are easily broken, so that reliability of the packaging is not good; material cost and process cost of gold wiring process for the current LED integrated packaging technology is high; circuits formed based on structures of a substrate, a chip, and gold wires are simple, so that functions of such circuits are limited.

### BRIEF SUMMARY

Not Applicable.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 schematically illustrates an LED integrated packaging structure of one embodiment of the present invention.

FIG. 2 schematically illustrates an LED integrated packaging structure of another embodiment of the present invention.

FIG. 3 (3A-3D) schematically illustrates an LED integrated packaging method embodiment of the present invention.

### DETAILED DESCRIPTION

### Glossary

Not Applicable.

### Description

Embodiments of an LED integrated packaging structure and an LED integrated packaging method are described providing improved integration, reliability, cost, and diversity of functions.

One embodiment includes an LED integrated packaging structure, with a base, at least one LED chip which is fixedly connected on the base, the LED chip having a positive electrode and a negative electrode, an insulation layer which is disposed on surfaces of the base and the LED chip and the, wherein surfaces of the positive and negative electrodes of the LED chip are exposed from the insulation layer, and at least two connecting electrodes which are disposed on the base and the LED chip. A height limiting ring may be disposed along edges of the base, and the LED chip is in the height limiting ring. Chip patterns may be printed on the connecting electrodes.

Embodiments of an LED integrated packaging method include 1) fixing an LED chip having positive and negative electrodes onto a base, 2) applying filler onto surfaces of the LED chip and the base and the, 3) removing, by a plate polishing process, a portion of the filler on the surfaces of the LED chip and the base and the until the surfaces of the positive and negative electrodes of the LED chip are exposed, and forming a plane from the surfaces of the LED chip and the base and the, 4) mounting, by a semiconductor process, connecting electrodes onto the LED chip and the base.

The LED integrated packaging method may further include fabricating electrode patterns on the connecting electrodes by photolithography process before step 4). The LED integrated packaging method may further include disposing a height limiting ring on edges of the base before step 1), the LED chip being in the height limiting ring.

In one embodiment the LED integrated packaging structure has an insulation layer disposed on surfaces of the base and the LED chip and the surfaces of the base and the LED chip form a plane and then the base and the LED chip are connected by the connecting electrodes. Compared with the prior art, this has the following advantages: through a structure including an LED chip, a base, an insulation layer and connecting electrodes, and through the formed plane, not only a single mesa device can be packaged, but also a plurality of mesa devices can be integratedly packaged, so that the integration is high; the reliability is higher by replacing the prior art gold wires with the connecting electrodes; compared with gold wiring, the material cost and process cost can be reduced by using the connecting electrodes; the formed plane and the disposed connecting electrodes provide conditions for subsequent fabrication of circuits which could be complex circuit designs like controlling circuits, so that the LED integrated packaging structure of the present invention has diverse functions. Moreover, flat surfaces of the connecting electrodes could facilitate to package a two-sides light-emitting structure.

Embodiments of a LED packaging method form a plane at the surfaces of the base and the LED chip and the mainly by filler and a plate polishing process and then connect the base and the LED chip by the connecting electrodes. Compared with the prior art, this has the following advantages: through providing an LED chip, a base, and connecting electrodes, and through the plane formed by applying filler, not only a single mesa device can be packaged, but also a plurality of mesa devices can be integratedly packaged, so that the integration is high; the reliability is higher by replacing the prior art gold wires with the connecting electrodes; compared with gold wiring, the material cost and process cost can be reduced by using the connecting electrodes; the formed plane and the disposed connecting electrodes provide conditions for subsequent fabrication of circuits which could be complex circuit designs like controlling circuits, so that the LED integrated packaging structure has diverse functions. Moreover, flat surfaces of the connecting electrodes the package of a two-sides light-emitting structure.

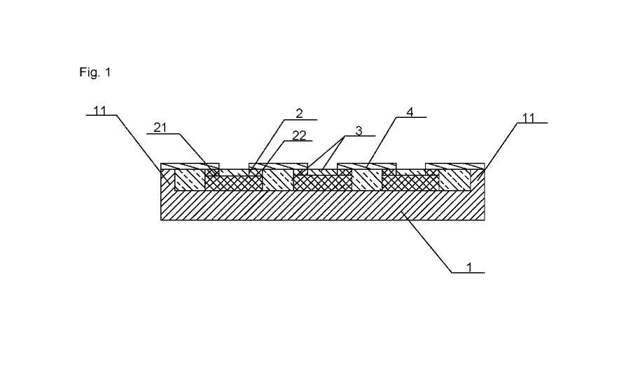

As shown in FIG. 1, in a first embodiment of an LED integrated packaging structure of the present invention, the structure includes: a base 1; three LED chips 2 which are fixedly connected onto the base 1, the LED chips 2 having positive and negative electrodes 21, 22; an insulation layer 3 which is disposed on surfaces of the base 1 and the LED chips 2, wherein surfaces of the positive and negative electrodes 21, 22 are exposed from the insulation layer 3, in other words, the insulation layer 3 combined with the base 1 and the LED chips 2 forms a flat surface but the positive and negative electrodes 21, 22 are exposed so as to mount connecting electrodes 4 later; four connecting electrodes 4 which are disposed on the base 1 and the LED chips 2. The insulation layer 3 could be made of P-Si glass, epoxy plastics, and transparent resins which have characteristics like insulation, transparency. Through these materials, the insulation layer 3 also has functions of light-reflecting, light-converging so as to reduce light loss. The connecting electrodes 4 could be mounted onto the base 1 and the LED chips 2 by a semiconductor process like an evaporation process, a sputtering process. Through the present structure including an LED chips 2, a base 1, an insulation layer 3 and connecting electrodes 4, and through the formed plane, not only a single mesa device can be packaged, but also a plurality of mesa devices can be integratedly packaged, so that the integration is high; the reliability is higher by replacing the prior art gold wires with the connecting electrodes 4; compared with gold wiring, the material cost and process cost can be reduced by using the connecting electrodes 4; the formed plane and the disposed connecting electrodes 4 provide conditions for subsequent fabrication of circuits which could be complex circuit designs like controlling circuits, so that the LED integrated packaging structure of the present invention has diverse functions. Moreover, flat surfaces of the connecting electrodes 4 could facilitate to package a two-sides light-emitting structure.

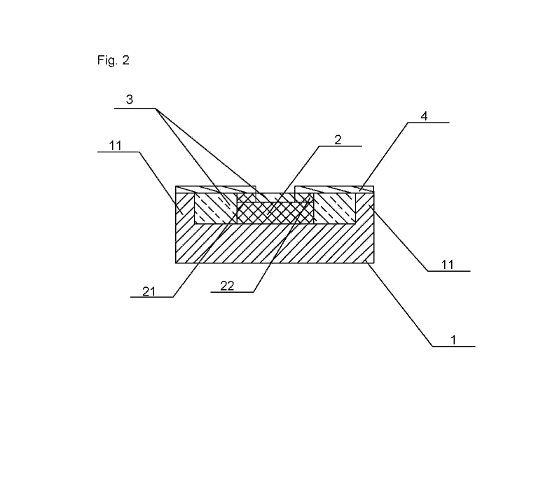

As shown in FIG. 2, in a second embodiment of an LED integrated packaging structure of the present invention, the structure includes: a base 1; one LED chip 2 which is fixedly connected onto the base 1, the LED chip 2 having positive and negative electrodes 21, 22; an insulation layer 3 which is disposed on surfaces of the base 1 and the LED chips 2, wherein surfaces of the positive and negative electrodes 21, 22 are exposed from the insulation layer 3, in other words, the insulation layer 3 combined with the base 1 and the LED chips 2 forms a flat surface but the positive and negative electrodes 21, 22 are exposed so as to mount connecting electrodes 4 later; two connecting electrodes 4 which are disposed on the base 1 and the LED chip 2. The present embodiment could be an alternative of the above first embodiment, and could be applied to a case of packaging a single mesa device, and has the same advantages as the above first embodiment.

As shown in FIGS. 1 and 2, in a third embodiment of an LED integrated packaging structure of the present invention, based on the above first or second embodiment, a height limiting ring 11 is disposed along edges of the base 1, and the LED chip 2 is in the height limiting ring 11. To assure security and steadiness, the height limiting ring 11 could be integral with the base 1. The height limiting ring 11 is provided for the height and flatness of the insulation layer 3.

In a fourth embodiment of an LED integrated packaging structure of the present invention, based on the above first, second, or third embodiment, chip patterns (not illustrated) could be printed on the above connecting electrodes, specifically by a silicon process like a photolithography process. The connecting electrodes with the chip patterns printed thereon could achieve more circuit designs. The patterns of the electrodes could be drawn based on practical needs.

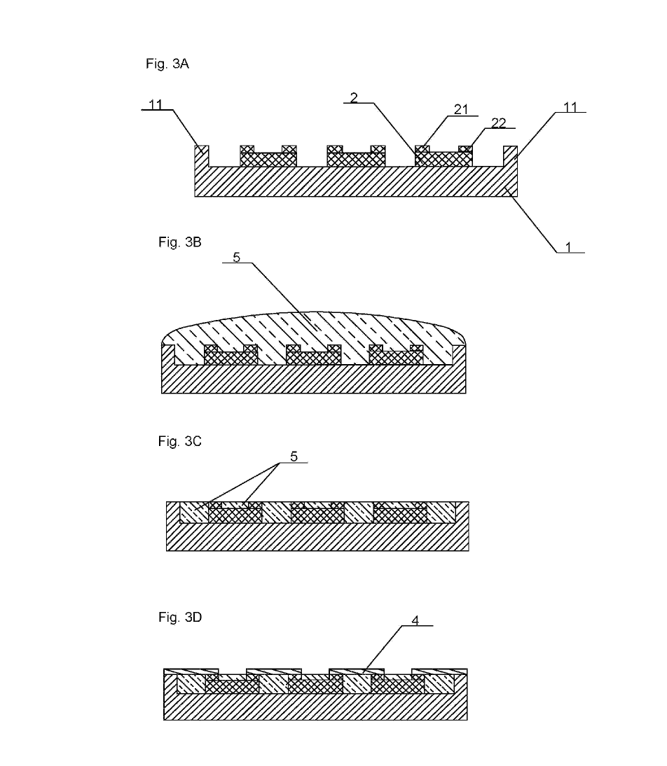

As shown in FIGS. 3A-3D, in a first embodiment of an LED integrated packaging method of the present invention, the method comprises the following steps: 1) fixing LED chips 2 having positive and negative electrodes 21, 22 onto a base 1, the result being shown in FIG. 3A; 2) applying filler 5 onto surfaces of the LED chips 2 and the base 1, the result being shown in FIG. 3B; 3) removing, by a plate polishing process, a portion of the filler 5 on the surfaces of the LED chips 2 and the base 1 until the surfaces of the positive and negative electrodes 21, 22 of the LED chips 2 are exposed, and forming a plane covering the surfaces of the LED chips 2 and the base 1, the result being shown in FIG. 3C; 4) mounting, by a semiconductor process, connecting electrodes 4 onto the LED chips 2 and the base 1, the result being shown in FIG. 3D. The base 1 could be made of metals (Al, Cu, etc.), ceramics, or plastics by thermal deposition. Compared with the prior art metal wiring board, such a base could have less thermal resistance. A wiring board could of course be used directly based on practical needs. The LED chips 2 could be fixed onto the base 1 by an alloy process or through use of heat-transfer glue bonding. The filler 5 could be made of P—Si glass, epoxy plastics, and transparent resins which have characteristics like insulation, transparency, and polishableness. These materials provide the insulation layer 3 with functions of light-reflecting, light-converging so as to reduce light loss. The semiconductor process could be an evaporation process, a sputtering process, and the like. The semiconductor process and the plate polishing process are well-known in the art, so the detailed description thereof is omitted here.

In a second embodiment of an LED integrated packaging method of the present invention, based on the above first embodiment, the method further comprises fabricating electrode patterns (not illustrated) on the connecting electrodes specifically by a silicon process like a photolithography process before the step 4). The connecting electrodes with the chip patterns printed thereon could achieve circuit designs with more functions. The patterns of the electrodes could be drawn based on practical needs.

As shown in FIG. 3A, in a third embodiment of an LED integrated packaging method of the present invention, based on the above first or second embodiment, the method further comprises disposing a height limiting ring 11 on edges of the base 1 before the step 1), the LED chips 2 being in the height limiting ring 11. To assure security and steadiness, the height limiting ring 11 could be integral with the base 1. The height limiting ring 11 could provide a height reference when the filler 5 is polished so that the polished filler 5 could obtain desired height and flatness.

Although specific embodiments of the invention have been described above in detail, the description is merely for purposes of illustration. It should be appreciated, therefore, that many aspects of the invention were described above by way of example only and are not intended as required or essential elements of the invention unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the invention defined in the following claim(s), the scope of which is to be accorded the broadest interpretation so as to encompass such modifications and equivalent structures.

### DRAWINGS

FIG. 1 schematically illustrates an LED integrated packaging structure of one embodiment of the present invention.

FIG. 2 schematically illustrates an LED integrated packaging structure of another embodiment of the present invention.

FIG. 3 (3A-3D) schematically illustrates an LED integrated packaging method embodiment of the present invention.

1. An LED integrated packaging structure, comprising:
a base;
a plurality of LED chips which are fixedly connected onto the base, the LED chips each having a positive electrode and a negative electrode;
an insulation layer which is disposed on surfaces of the base and the LED chip, wherein surfaces of the positive electrode and the negative electrode and the LED chips are exposed from the insulation layer and the surfaces of the LED chip and the base form a plane;
each LED chip separated from an adjacent LED chip by only material of the insulation layer;
the material of the insulation layer forming vertical walls abutting the LED chips and separating adjacent LED chips; and
a plurality of connecting electrodes spanning the vertical walls to connect the negative electrode and positive electrode of adjacent LED chips.

2. The LED integrated packaging structure of claim 1, wherein a height limiting ring is disposed along edges of the base, and the LED chips is within the height limiting ring.

3. (canceled)

4. An LED integrated packaging method, comprising the steps of:
(a) fixing an LED chips having a positive electrode and a negative electrode onto a base;
(b) applying filler onto surfaces of the LED chip and the base, the filler forming vertical walls abutting the LED chips and forming the entire separation between adjacent LED chips;
(c) removing, by a plate polishing process, a portion of the filler on the surfaces of the LED chip and the base and the until surfaces of the positive electrode and the negative electrode of the LED chips are exposed, and forming a plane from the surfaces of the LED chip and the base; and
(d) mounting, by a semiconductor process, connecting electrodes onto the LED chips and the base, the connecting electrodes spanning the vertical wall of filler material to connect the negative electrode of an LED chip with the positive electrode of an adjacent LED chip.

5. (canceled)

6. The LED integrated packaging method of claim 4, further comprising:
disposing a height limiting ring on edges of the base before the step (a), the LED chips being within the height limiting ring.
